(19) United States
(12) Patent Application Publication
(10) Pub. No.: US 2021/0141313 A1
(43) Pub. Date: May 13, 2021

(54) RESIN CASSETTES

(71) Applicant: Carbon, Inc., Redwood City, CA (US)

(72) Inventors: Jean-Claude de Sugny, San Francisco, CA (US); Sean Patrick Wheeler, San Jose, CA (US); Anant Chimmalgi, Los Altos, CA (US)

(21) Appl. No.: 17/073,654

(22) Filed: Oct. 19, 2020

Related U.S. Application Data
(60) Provisional application No. 62/923,768, filed on Oct. 21, 2019.
(60) Provisional application No. 62/947,246, filed on Dec. 12, 2019.

(51) Int. Cl. G03F 7/20; B29C 64/106; G03F 7/00

(52) U.S. Cl. CPC G03F 7/70416; B33Y 10/00; G03F 7/0037; B29C 64/106

(57) ABSTRACT

A cassette includes a light transmissive window through which a temporally and spatially modulated image is passed. The window has a bottom surface, as part of the cassette, or as a separate component which may be separately interchangeable in the apparatus, or a part of the apparatus. In some embodiments: (i) the window bottom surface comprises a convex surface or consists essentially of a convex surface (e.g., without additional optical structure associated therewith); (ii) the window bottom surface comprises a concave surface or consists essentially of a concave surface (e.g., without additional optical structure associated therewith); (iii) the window bottom surface has a diffraction grating or Fresnel lens thereon or operatively associated therewith; (iv) a combination of (i) and (iii); or (v) a combination of (ii) and (iii).

### RELATED APPLICATIONS

This application claims priority to U.S. Provisional Application Ser. No. 62/923,768, filed Oct. 21, 2019, and U.S. Provisional Application Ser. No. 62/947,246, filed Dec. 12, 2019, the disclosures of which are incorporated herein in its entirety.

### FIELD OF THE INVENTION

The present invention concerns apparatus for producing objects by additive manufacturing.

### BACKGROUND OF THE INVENTION

A group of additive manufacturing techniques sometimes referred to as “stereolithography” creates a three-dimensional object by the sequential polymerization of a light polymerizable resin. Such techniques may be “bottom-up” techniques, where light is projected into the resin on the bottom of the growing object through a light transmissive window, or “top down” techniques, where light is projected onto the resin on top of the growing object, which is then immersed downward into the pool of resin.

The recent introduction of a more rapid stereolithography technique known as continuous liquid interface production (CLIP), coupled with the introduction of “dual cure” resins for additive manufacturing, has expanded the usefulness of stereolithography from prototyping to manufacturing (see, e.g., U.S. Pat. Nos. 9,211,678; 9,205,601; and 9,216,546 to DeSimone et al.; and also in J. Tumbleston, D. Shirvanyants, N. Ermoshkin et al., Continuous liquid interface production of 3D Objects, Science 347, 1349-1352 (2015); see also Rolland et al., U.S. Pat. Nos. 9,676,963, 9,453,142 and 9,598,606).

In many advanced stereolithography processes, there is a delicate balance between part production accuracy, part production speed, chemical reaction requirements, and chemical reaction consequences. Optimizing one parameter, such as accuracy, may be deleterious to another parameter such as production speed. Increasing speed, on the other hand, may lead to greater heat generation and more rapid consumption of polymerization inhibitors such as oxygen. Numerous other variables can come into play. Accordingly, there remains a need for improvements in advanced stereolithography processes and apparatus that can better tune or adapt the process for specific production scenarios.

### SUMMARY OF THE INVENTION

Bottom-up additive manufacturing (stereolithography) apparatus, and in some embodiments, removable cassettes therefor, are described. The apparatus or the cassettes include a light transmissive window through which a temporally and spatially modulated image is passed. The window has a bottom surface, as part of the cassette, or as a separate component which may be separately interchangeable in the apparatus, or a part of the apparatus. In some embodiments: (i) the window bottom surface comprises a convex surface or consists essentially of a convex surface (e.g., without additional optical structure associated therewith); (ii) the window bottom surface comprises a concave surface or consists essentially of a concave surface (e.g., without additional optical structure associated therewith); (iii) the window bottom surface has a diffraction grating or Fresnel lens thereon or operatively associated therewith; (iv) a combination of (i) and (iii); or (v) a combination of (ii) and (iii).

In some embodiments, the geometrical concave and convex shapes for the window bottom surface may address two issues, including field curvature and telecentricity. Adding the diffractive or Fresnel features may be useful in some embodiments for improving telecentricity. Thus, there are several combinations of geometries and Fresnel features that may be used depending on, for example, a particular production scenario being employed.

The concave shape for the window bottom surface may addresses optical field curvature, where points on the edge of the build plane tend to conic to focus at a lower height than in the center, which may be less preferred since the build area itself (where resin is being polymerized) is a flat surface. This can require adding optical complexity to the projection lens of the light engine itself, increasing the cost of the light engine. If this is compensated for by a concave surface at the bottom of the window (particularly where windows are interchangeable cassettes, and only those cassettes required for production processes requiring such accuracy were so modified), the light engine itself can be simplified.

The bulk convex shape for the window bottom surface, on the other hand, may address the need for improved telecentricity through the window, particularly where the window includes internal features such as channels for enhancing the flow of an inhibitor such as oxygen (preferred for greater production speeds) that might otherwise scatter light.

There is, however, some subtlety here, because improving telecentricity may only requires that the surface have positive optical power (which a convex surface has) rather than a specific bulk shape. So, other optical features, such as the aforementioned diffractive and fennel features can be included. Addressing the problem of field curvature close to the build plane, on the other hand, may require that there be a bulk volume of window, so that the rays at the edge of the build plane have a longer path through glass than the rays at the center of the window.

Thus, a window with a simple concave bottom surface alone can be used if all the specific production process requires is reduction of field curvature effects. On the other hand, if the specific production process requires improving telecentricity, then a simple convex surface alone can be used. And, a concave surface in combination with a diffractive or Fresnel feature can be used to improve both issues. The combination of convex surface with a diffractive or Fresnel feature is also a valid approach to improving telecentricity, but can be useful if strong, or highly sculpted, convex surface is less preferred. Finally, if only reducing telecentricity is a concern, then one can use a surface with no curvature, and just a diffractive of Fresnel feature.

In some embodiments, a resin cassette for an additive manufacturing apparatus is provided. The apparatus includes a light engine and a cassette mount operatively associated therewith, and the light engine is configured for projecting an enlarged image through the resin cassette when positioned on the cassette mount. The resin cassette includes (a) a light transmissive window configured to pass the enlarged image therethrough. The window has a bottom surface such that (i) the window bottom surface comprises a convex surface or consists essentially of a convex surface (e.g., without additional optical structure associated therewith); (ii) the window bottom surface comprises a concave surface or consists essentially of a concave surface (e.g., without additional optical structure associated therewith); (iii) the window bottom surface has a diffraction grating or Fresnel lens thereon or operatively associated therewith; (iv) a combination of (i) and (iii) or (v) a combination of (ii) and (iii). The cassette further includes (b) a circumferential frame connected to and surrounding the window, the window and frame together forming a well configured to receive a light polymerizable resin.

In some embodiments, the bottom surface is concave and configured to reduce field curvature effects as the enlarged image passes therethrough.

In some embodiments, the bottom surface further comprises a diffraction grating or Fresnel lens configured to enhance telecentricity of the enlarged image as passing through the window.

In some embodiments, the bottom surface is convex and configured to enhance telecentricity of the enlarged image as passing through the window.

In some embodiments, the bottom surface is convex and further comprises a diffraction grating or Fresnel lens configured to further enhance telecentricity of the image as passing through the window.

In some embodiments, the bottom surface is planar, and further comprises a diffraction grating or Fresnel lens configured to enhance telecentricity of the enlarged image as passing through the window.

In some embodiments, the cassette further includes a unique identifier (e.g., an NFC tag, an RFID tag, etc.) connected to the circumferential frame.

In some embodiments, the window includes internal structures defining fluid flow passages therein, with the internal structures distributed across the length and width of the window, and with the internal structures creating reflective and/or refractive surfaces within the window.

In some embodiments, the window comprises a sandwich of at least a top portion an intermediate portion, and a bottom portion, and the internal structures are formed in the intermediate portion.

In some embodiments, the window bottom portion comprises glass, sapphire, quartz, or transparent aluminum (aluminum oxynitride; ALON).

In some embodiments, the top portion comprises a polymer (e.g., an oxygen-permeable polymer such as an amorphous fluoropolymer).

In some embodiments, the intermediate layer comprises a second polymer layer, such as a polydimethylsiloxane (PDMS) layer.

In some embodiments, a bottom-up additive manufacturing apparatus includes (a) a frame; (b) a resin cassette comprising: (i) a light transmissive window configured to pass the enlarged image therethrough, the window having a bottom surface, the cassette further comprising: (ii) a circumferential frame connected to and surrounding the window, the window and frame together forming a well configured to receive a light polymerizable resin; (c) a light source positioned below the resin cassette and positioned for projecting an enlarged image through the window; (d) a removable carrier platform or a carrier platform engagement assembly positioned above the window and operatively associated with the frame; and (e) a drive operatively associated with the carrier and the frame and configured for advancing the carrier platform and the resin cassette away from one another (e.g., in the Z or vertical direction); and wherein: (i) the window bottom surface comprises a convex surface or consists essentially of a convex surface (e.g., without additional optical structure associated therewith); (ii) the window bottom surface comprises a concave surface or consists essentially of a concave surface (e.g., without additional optical structure associated therewith); (iii) the window bottom surface has a diffraction grating or Fresnel lens thereon or operatively associated therewith (e.g., as either part of the cassette, or as part of the bottom-up additive manufacturing apparatus, or as a separate interchangeable component); (iv) a combination of (i) and (iii) or (v) a combination of (ii) and (iii).

In some embodiments, the light source comprises a micromirror array or liquid crystal display (LCD) panel.

In some embodiments, the apparatus further includes an inhibitor supply (e.g., an oxygen concentrator) operatively associated with the resin cassette fluid flow passages.

In some embodiments, the apparatus further includes a controller operatively associated with the light source and the drive.

In some embodiments, the apparatus further includes a unique identifier (e.g., an NFC tag, an RFID tag, etc.) connected to the circumferential frame; and an identifier reader operatively associated with the controller.

In some embodiments, the bottom surface is concave and configured to reduce field curvature effects as the enlarged image passes therethrough.

In some embodiments, the bottom surface is concave and further comprises a diffraction grating or Fresnel lens configured to enhance telecentricity of the enlarged image as passing through the window.

In some embodiments, the bottom surface is convex and configured to enhance telecentricity of the enlarged image as passing through the window.

In some embodiments, the bottom surface is convex and further comprises a diffraction grating or Fresnel lens configured to further enhance telecentricity of the image as passing through the window.

In some embodiments, the bottom surface is planar, and further comprises a diffraction grating or Fresnel lens configured to enhance telecentricity of the enlarged image as passing through the window.

In some embodiments, the window has internal structures (e.g., channels) defining fluid flow passages therein, with the internal structures distributed across the length and width of the window, and with the internal structures creating reflective and/or refractive surfaces within the window.

In some embodiments, the window comprises a sandwich of at least a top portion an intermediate portion, and a bottom portion, and the internal structures are formed in the intermediate portion; optionally wherein: the window bottom portion comprises glass, sapphire, quartz, or transparent aluminum (aluminum oxynitride; ALON); and/or the top portion comprises a polymer (e.g., an oxygen-permeable polymer such as an amorphous fluoropolymer); and/or the intermediate layer comprises a second polymer layer, such as a polydimethylsiloxane (PDMS) layer.

In some embodiments, the resin cassette is fixed and stationary in the lateral (X and Y) directions.

In some embodiments, a method of making an object from a light polymerizable resin and a data file (e.g., a CAD file, an .stl file, a .3mf file etc.) includes (a) filling a resin cassette in an apparatus of claims 13 to 25 with the resin; and (b) producing the object from the data file and the resin by intermittently and/or continuously exposing the resin to an enlarged image from the light source to photopolymerize the resin, while advancing the carrier platform and the resin cassette away from one another.

In some embodiments, the resin comprises a dual cure resin.

The foregoing and other objects and aspects of the present invention are explained in greater detail in the drawings herein and the specification set forth below. The disclosures of all United States patent references cited herein are to be incorporated herein by reference.

### BRIEF DESCRIPTION OF THE DRAWINGS

FIG. 1 is a schematic illustration of one embodiment of an apparatus as described herein, showing as dashed lines the divergent chief rays of an image projected from the light source.

FIG. 2A is a top plan view of the resin cassette in FIG. 1, showing (as nested elliptical dashed lines) the increasingly divergent chief rays of an image projected from the light source.

FIG. 2B is a side sectional view of one embodiment of a resin cassette, showing different layers in the window.

FIG. 3 shows light refracted and reflected by a channel (c) having a quadrangular (specifically, a rectangular) profile in a typical resin cassette, leading to substantial “ghosting” of the image when projected into the resin.

FIG. 4A schematically illustrates a window for an additive manufacturing apparatus having a concave bottom surface.

FIG. 4B schematically illustrates how a concave window bottom surface reduces field curvature effects, but also reduces telecentricity of rays in the window.

FIG. 5A schematically illustrates a window for an additive manufacturing apparatus having a convex bottom surface.

FIG. 5B schematically illustrates how a convex window bottom surface enhances telecentricity in the window (but also exacerbates field curvature effects).

FIG. 6A schematically illustrates a window for an additive manufacturing apparatus having a concave bottom surface, and with a Fresnel lens or diffractive surface associated therewith.

FIG. 6B schematically illustrates how a concave window bottom surface, in combination with a Fresnel Lens or diffractive surface, both reduces field curvature effects, and enhances telecentricity of rays in the window.

FIG. 7 schematically illustrates a window having a convex bottom surface, and with a Fresnel lens or diffractive surface associated therewith.

FIG. 8 schematically illustrates a window having a planar bottom surface, and with a Fresnel lens or diffractive surface associated therewith.

### DETAILED DESCRIPTION OF ILLUSTRATIVE EMBODIMENTS

The present invention is now described more fully hereinafter with reference to the accompanying drawings, in which embodiments of the invention are shown. This invention may, however, be embodied in many different forms and should not be construed as limited to the embodiments set forth herein; rather these embodiments are provided so that this disclosure will be thorough and complete and will fully convey the scope of the invention to those skilled in the art.

As used herein, the term “and/or” includes any and all possible combinations of one or more of the associated listed items, as well as the lack of combinations when interpreted in the alternative (“or”).

1. Resin and Additive Manufacturing Apparatus.

Resins for additive manufacturing are known and described in, for example, U.S. Pat. Nos. 9,211,678; 9,205,601; and 9,216,546 to DeSimone et al. In addition, dual cure resins useful for carrying out some embodiments of the present invention are known and described in U.S. Pat. Nos. 9,676,963, 9,453,142 and 9,598,606 to Rolland et al., and in U.S. Pat. No. 10,316,213 to Arndt et al. Particular examples of suitable dual cure resins include, but are not limited to, Carbon Inc. medical polyurethane, elastomeric polyurethane, rigid polyurethane, flexible polyurethane, cyanate ester, epoxy, and silicone dual cure resins, all available from Carbon, Inc., 1089 Mills Way, Redwood City, Calif. 94063 USA.

Apparatus for carrying out bottom-up stereolithography, which can be adapted or improved as described herein, are known and described in, for example, U.S. Pat. No. 5,236,637 to Hull, U.S. Pat. Nos. 5,391,072 and 5,529,473 to Lawton, U.S. Pat. No. 7,438,846 to John, U.S. Pat. No. 7,892,474 to Shkolnik, U.S. Pat. No. 8,110,135 to El-Siblani, U.S. Patent Application Publication No. 2013/0292862 to Joyce, and US Patent Application Publication No. 2013/0295212 to Chen et al. The disclosures of these patents and applications are incorporated by reference herein in their entirety.

In some embodiments, the additive manufacturing step is carried out by one of the family of methods sometimes referred to as as continuous liquid interface production (CLIP). CLIP is known and described in, for example, U.S. Pat. Nos. 9,211,678; 9,205,601; 9,216,546; and others; in J. Tumbleston et al., Continuous liquid interface production of 3D Objects, Science 347, 1349-1352 (2015); and in R. Janusziewcz et al., Layerless fabrication with continuous liquid interface production, Proc. Natl. Acad. Sci. USA 113, 11703-11708 (Oct. 18, 2016). Other examples of methods and apparatus for carrying out particular embodiments of CLIP include, but are not limited to: Batchelder et al., US Patent Application Pub. No. US 2017/0129169 (May 11, 2017); Sun and Lichkus, US Patent Application Pub. No. US 2016/0288376 (Oct. 6, 2016); Willis et al., US Patent Application Pub. No. US 2015/0360419 (Dec. 17, 2015); Lin et al., US Patent Application Pub. No. US 2015/0331402 (Nov. 19, 2015); D. Castanon, S Patent Application Pub. No. US 2017/0129167 (May 11, 2017). B. Feller, US Pat App. Pub. No. US 2018/0243976 (published Aug. 30, 2018); M. Panzer and J. Tumbleston, US Pat App Pub. No. US 2018/0126630 (published May 10, 2018); and K. Willis and B. Adzima, US Pat App Pub. No. US 2018/0290374 (Oct. 11, 2018).

2. Image Projection and Ghosting

As can be seen from FIGS. 1-2A, when an enlarged image is projected from a light source (such as an image projected off of a micromirror array or an image formed by projection through a liquid crystal display), the principal rays of the image diverge from substantially perpendicular at the point where they encounter the window to an increasingly greater angle of incidence.

As schematically illustrated in FIG. 3, when the window includes internal features such as rectangular channels, the principal rays of the image can (depending on the channel shape and the location of that channel segment) refract, reflect, or both refract and reflect, off of the channel in a progressively increasing fashion along the channel as the rays increasingly diverge from the perpendicular point. This can cause reflective and/or refractive “ghosting” of the image in these portions of the window, leading to problems such as decrease in accuracy, and/or a decrease in delivery of the intended light dose to the resin, for objects produced in these portions of the regions. A reduced telecentricity in the window can cause light to reflect and/or refract from internal window features.

3. Resin Cassettes and Apparatus.

FIGS. 1, 2A, and 2B show a bottom-up additive manufacturing apparatus and corresponding resin cassette, including: (a) a frame (17); (b) a resin cassette (10) including: (i) a light transmissive window (11) configured to pass the enlarged image therethrough, the window having a bottom surface, the cassette further comprising: (ii) a circumferential frame (12) connected to and surrounding the window, the window and frame together forming a well configured to receive a light polymerizable resin (e.g., 21); (c) a light source (e.g., 13) positioned below the resin cassette and positioned for projecting an enlarged image through the window; (d) a removable carrier platform (14) or a carrier platform engagement assembly (14a) positioned above the window and operatively associated with the frame; and (e) a drive (15) operatively associated with the carrier and the frame and configured for advancing the carrier platform and the resin cassette away from one another (typically in the “Z” or vertical direction, and typically by moving the platform upward and away from an otherwise stationary window).

FIG. 2A is a top plan view of the resin cassette in FIG. 1, showing (as nested elliptical dashed lines) the increasingly divergent chief rays of an image projected from the light source.

The apparatus and/or cassette is further characterized in that: (i) the window bottom surface comprises a convex surface or consists essentially of a convex surface (e.g., without additional optical structure associated therewith); (ii) the window bottom surface comprises a concave surface or consists essentially of a concave surface (e.g., without additional optical structure associated therewith); (iii) the window bottom surface has a diffraction grating or Fresnel lens thereon or operatively associated therewith (e.g., as either part of the cassette, or as part of the bottom-up additive manufacturing apparatus, or as a separate interchangeable component); (iv) a combination of (i) and (iii) or (v) a combination of (ii) and (iii).

Any suitable light source can be used, such as one employing an ultraviolet light, projecting off of a micromirror array or through a liquid crystal display (LCD) panel.

The apparatus preferably includes a source or supply of inhibitor (not shown), such as an oxygen concentrator, that is connected to the resin cassette, and specifically to the flow passages in the resin cassette, (preferably by quick connectors) to a removable cassette, such as described in Feller and Griffin, PCT Patent Application Pub. No. WO 2019/084112, and in Feller et al., PCT Patent Application Pub. No. WO 2018/006018.

The apparatus may include a controller (16), such as a general purpose computer, located on board the apparatus, on the cloud, or a combination thereof, operatively associated with the light source and drive, and including programming for carrying out additive manufacturing on the apparatus as is known in the art.

The apparatus can optionally include heaters and/or coolers operatively associated with the window and the controller. Any suitable devices can be used, including resistive heaters, Peltier coolers, infrared heaters, etc., including combinations thereof. The heaters/coolers are preferably directly included in the resin cassette, preferably in direct contact with the window itself, or in the case of infrared heaters can be positioned to project into the resin through the window.

The cassette (10), as noted above, generally includes a light transmissive window (11) configured to pass the enlarged image therethrough. The cassette includes a circumferential frame (12) connected to and surrounding the window, the window and frame together forming a well configured to receive a light polymerizable resin (e.g., 21).

As illustrated in FIG. 3, in some embodiments (where an inhibitor of polymerization such as oxygen is supplied so that the production process can proceed more quickly) the window has internal structures defining fluid flow passages therein, with the internal structures distributed across the length and width of the window, and with the internal structures creating reflective and/or refractive surfaces within the window.

A variety of geometries for these internal structures can be employed: in some embodiments, internal structures comprise walls and the passages comprise laterally aligned (e.g., parallel) channels; in some embodiments the internal structures comprise pillars (of any shape, width, and length) and the passages may comprise regularly or irregularly intersecting channels. The channels themselves may be of any suitable profile, such triangular and/or quadrangular (e.g., square, rectangular, parallelogram, etc.) in profile.

The cassette window can be constructed in any suitable manner, though preferably provides or includes an oxygen permeable top portion through which oxygen in fluid flow passages can pass through to resin on top of the window. In some embodiments, the window comprises a sandwich of at least top portion (11a) an intermediate portion (11b), and a bottom portion (11c), with the internal structures, when present, formed in the intermediate portion.

In some embodiments, the window bottom portion, comprises glass, sapphire, quartz, or transparent aluminum (aluminum oxynitride; ALON).

In some embodiments, the window top portion comprises a polymer (e.g., an oxygen-permeable polymer such as an amorphous fluoropolymer), optionally with the fluorophore dispersed therein.

In some embodiments, the intermediate layer comprises a second polymer layer, such as a polydimethylsiloxane (PDMS) layer.

The resin cassette can include a unique identifier (26a) (e.g., a passive identifying element, such as an NFC tag, an RFID tag, a barcode, QR code, etc.), typically connected to the circumferential frame; and the apparatus can include a corresponding identifier reader (26b) operatively associated with the controller. In use, the reader can detect the identity and type of resin cassette, and the controller can include instructions for modifying the output of the light engine appropriate for the type of cassette received (e.g., any of the different types of cassettes described herein above and below). Thus, the user can select an interchangeable cassette that best matches their needs for the particular type of object being produced, from the particular resin being used, without the need to customize the entire apparatus (particular the light engine) for one specific use.

As shown in FIGS. 4A-4B, in some embodiments, the bottom surface (11cc) of the window (11) is concave and configured to reduce field curvature effects as the enlarged image passes therethrough. In some embodiments, the bottom concave surface (11cc) reduces telecentricity in the window as well as field curvature effects.

As shown in FIGS. 6A-6B, in some embodiments, the bottom surface (11cc) is concave and further comprises a diffraction grating or Fresnel lens (40) configured to enhance telecentricity of the enlarged image as passing through the window (e.g., FIGS. 6A-6B). In this configuration, the field curvature effects may be reduced and the telecentricity may be enhanced.

As shown in FIGS. 5A-5B, in some embodiments the bottom surface is convex (11cv) and configured to enhance telecentricity of the enlarged image as passing through the window, although field curvature effects may be enhanced.

As shown in FIG. 7, in some embodiments the bottom surface (11cv) of the window (11) is convex and further comprises a diffraction grating or Fresnel lens (40) configured to further enhance telecentricity of the image as passing through the window (e.g., so that less curvature of the convex surface is required to achieve the same effect)).

As shown in FIG. 8, in some embodiments the bottom surface (11p) of the window (11) is planar, and further comprises a diffraction grating or Fresnel lens (40) configured to enhance telecentricity of the enlarged image as passing through the window.

While the Figures generally show the layers of the window in contact with one another, note that, in some embodiments, the layers of the window may be separated by a gap (such as where a diffraction grating or Fresnel lens is a separately interchangeable component (separate from both the resin cassette and the apparatus) or affixed to the apparatus itself.\

In use, the cassettes and apparatus described herein provide a method of making an object (31) from a light polymerizable resin (21) and a data file (e.g., a CAD file, an .stl file, a .3mf file, etc.), by (a) filling a resin cassette in an apparatus of claim with a resin such as described above (e.g., a dual cure resin), and then (b) producing the object from the data file and the resin by intermittently and/or continuously exposing the resin to an enlarged image (e.g., that is spatially and temporally modulated) from the light source to photopolymerize the resin, while advancing the carrier platform and the resin cassette away from one another.

4. Magnesium Fluoride Windows.

For a window having a heater and/or cooler operatively associated therewith, utilizing magnesium fluoride for the window bottom portion is attractive because of its favorable heat conduction properties. But magnesium fluoride is inherently birefringent, which may cause multiple image projections, particularly around the periphery thereof problematic for accurate additive manufacturing. This problem is further exacerbated by its lesser strength than materials such as ALON, requiring it to be thicker (and in turn exacerbating the birefringence). A solution to this problem is to employ any of the features described herein to enhance telecentricity to help mitigate the birefringence inherent in the magnesium fluoride material.

Another solution to the birefringence problem alone or in combination with the foregoing, is to use two layers of magnesium fluoride material as a window bottom portion, with one aligned orthogonally to the other (that is, offset 90 degrees from one another so that the “extraordinary” axis of the crystals are at right angles).

Still another solution to the birefringence problem is to align the crystal axis of the magnesium fluoride bottom portion with the direction of propagation of light through the window, reducing the birefringence by a factor of cosine and hence to a level within acceptable tolerances.

The foregoing is illustrative of the present invention, and is not to be construed as limiting thereof. The invention is defined by the following claims, with equivalents of the claims to be included therein.

We claim:

1. A resin cassette for an additive manufacturing apparatus, the apparatus having a light engine and a cassette mount operatively associated therewith, the light engine configured for projecting an enlarged image through said resin cassette when positioned on said cassette mount, said resin cassette comprising:
(a) a light transmissive window configured to pass the enlarged image therethrough, the window having a bottom surface, wherein:
(i) said window bottom surface comprises a convex surface or consists essentially of a convex surface;
(ii) said window bottom surface comprises a concave surface or consists essentially of a concave surface;
(iii) said window bottom surface has a diffraction grating or Fresnel lens thereon or operatively associated therewith;
(iv) a combination of (i) and (iii); or
(v) a combination of (ii) and (iii);
said cassette further comprising:
(b) a circumferential frame connected to and surrounding said window, said window and frame together forming a well configured to receive a light polymerizable resin.

2. The resin cassette of claim 1, wherein said bottom surface is concave and configured to reduce field curvature effects as said enlarged image passes therethrough.

3. The resin cassette of claim 2, wherein said bottom surface further comprises a diffraction grating or Fresnel lens configured to enhance telecentricity of said enlarged image as passing through said window.

4. The resin cassette of claim 1, wherein said bottom surface is convex and configured to enhance telecentricity of said enlarged image as passing through said window.

5. The resin cassette of claim 4, wherein said bottom surface is convex and further comprises a diffraction grating or Fresnel lens configured to further enhance telecentricity of said image as passing through said window.

6. The resin cassette of claim 1, wherein said bottom surface is planar, and further comprises a diffraction grating or Fresnel lens configured to enhance telecentricity of said enlarged image as passing through said window.

7. The resin cassette of claim 1, further comprising a unique identifier connected to said circumferential frame.

8. The resin cassette of claim 1, the window having internal structures defining fluid flow passages therein, with the internal structures distributed across the length and width of said window, and with the internal structures creating reflective and/or refractive surfaces within said window.

9. The cassette of claim 8, wherein said window comprises a sandwich of at least a top portion an intermediate portion, and a bottom portion, and said internal structures are formed in said intermediate portion.

10. The cassette of claim 9, where said window bottom portion comprises glass, sapphire, quartz, or transparent aluminum.

11. The cassette of claim 9, wherein said top portion comprises a polymer.

12. The cassette of claim 9, wherein said intermediate layer comprises a second polymer layer, such as a polydimethylsiloxane (PDMS) layer.

13. The cassette of claim 1, wherein said window bottom portion comprises magnesium fluoride.

14. The cassette of claim 13, further comprising a heater, a cooler, or a combination thereof operatively associated with said window bottom portion.

15. A bottom-up additive manufacturing apparatus, comprising:
(a) a frame;
(b) a resin cassette comprising:
(i) a light transmissive window configured to pass the enlarged image therethrough, the window having a bottom surface, said cassette further comprising:
(ii) a circumferential frame connected to and surrounding said window, said window and frame together forming a well configured to receive a light polymerizable resin;
(c) a light source positioned below said resin cassette and positioned for projecting an enlarged image through said window;
(d) a removable carrier platform or a carrier platform engagement assembly positioned above said window and operatively associated with said frame; and
(e) a drive operatively associated with said carrier and said frame and configured for advancing said carrier platform and said resin cassette away from one another; and wherein:
(i) said window bottom surface comprises a convex surface or consists essentially of a convex surface;
(ii) said window bottom surface comprises a concave surface or consists essentially of a concave surface;
(iii) said window bottom surface has a diffraction grating or Fresnel lens thereon or operatively associated therewith;
(iv) a combination of (i) and (iii); or
(v) a combination of (ii) and (iii).

16. The apparatus of claim 15, wherein said light source comprises a micromirror array or liquid crystal display (LCD) panel.

17. The apparatus of claim 15, further comprising an inhibitor supply operatively associated with said resin cassette fluid flow passages.

18. The apparatus of claim 15, further comprising a controller operatively associated with said light source and said drive.

19. The apparatus of claim 18, further comprising:
a unique identifier connected to said circumferential frame; and
an identifier reader operatively associated with said controller.

20. The apparatus of claim 15, wherein said bottom surface is concave and configured to reduce field curvature effects as said enlarged image passes therethrough.

21. The apparatus of claim 20, wherein said bottom surface is concave and further comprises a diffraction grating or Fresnel lens configured to enhance telecentricity of said enlarged image as passing through said window.

22. The apparatus of claim 15, wherein said bottom surface is convex and configured to enhance telecentricity of said enlarged image as passing through said window.

23. The apparatus of claim 22, wherein said bottom surface is convex and further comprises a diffraction grating or Fresnel lens configured to further enhance telecentricity of said image as passing through said window.

24. The apparatus of claim 15, wherein said bottom surface is planar, and further comprises a diffraction grating or Fresnel lens configured to enhance telecentricity of said enlarged image as passing through said window.

25. The apparatus of claim 15, the window having internal structures defining fluid flow passages therein, with the internal structures distributed across the length and width of said window, and with the internal structures creating reflective and/or refractive surfaces within said window.

26. The apparatus of claim 25, wherein:
said window comprises a sandwich of at least a top portion an intermediate portion, and a bottom portion, and said internal structures are formed in said intermediate portion; optionally wherein:
said window bottom portion comprises glass, sapphire, quartz, or transparent aluminum; and/or
said top portion comprises a polymer; and/or
said intermediate layer comprises a second polymer layer.

27. The apparatus of claim 15, wherein said resin cassette is fixed and stationary in the lateral (X and Y) directions.

28. The apparatus of claim 15, wherein said window bottom portion comprises magnesium fluoride.

29. The apparatus of claim 13, further comprising a heater, a cooler, or a combination thereof operatively associated with said window bottom portion.

26. A method of making an object from a light polymerizable resin and a data file comprising:
(a) filling a resin cassette with said resin, said resin cassette comprising:
a light transmissive window configured to pass the enlarged image therethrough, the window having a bottom surface, wherein:
(i) said window bottom surface comprises a convex surface or consists essentially of a convex surface;
(ii) said window bottom surface comprises a concave surface or consists essentially of a concave surface;
(iii) said window bottom surface has a diffraction grating or Fresnel lens thereon or operatively associated therewith;
(iv) a combination of (i) and (iii); or
(v) a combination of (ii) and (iii);
said cassette further comprising:
a circumferential frame connected to and surrounding said window, said window and frame together forming a well configured to receive a light polymerizable resin; and
(b) producing said object from said data file and said resin by intermittently and/or continuously exposing said resin to an enlarged image from said light source to photopolymerize said resin, while advancing said carrier platform and said resin cassette away from one another.

27. The method of claim 26, wherein said resin comprises a dual cure resin.
